(19) United States
(12) Patent Application Publication
(10) Pub. No.: US 2013/0222060 A1
(43) Pub. Date: Aug. 29, 2013

(54) MUTUALLY COUPLED MATCHING NETWORK

(71) Applicants: Chi Shun Lo, San Diego, CA (US); Jonghae Kim, San Diego, CA (US); Wesley Nathaniel Allen, Lafayette, IN (US); Chengjie Zuo, Santee, CA (US); Changhan Yun, San Diego, CA (US); Thomas Andrew Myers, San Diego, CA (US); Prasad Srinivasa Siva Gudem, San Diego, CA (US); Matthew Michael Nowak, San Diego, CA (US)

(72) Inventors: Chi Shun Lo, San Diego, CA (US); Jonghae Kim, San Diego, CA (US); Wesley Nathaniel Allen, Lafayette, IN (US); Chengjie Zuo, Santee, CA (US); Changhan Yun, San Diego, CA (US); Thomas Andrew Myers, San Diego, CA (US); Prasad Srinivasa Siva Gudem, San Diego, CA (US); Matthew Michael Nowak, San Diego, CA (US)

(73) Assignee: QUALCOMM INCORPORATED, San Diego, CA (US)

(21) Appl. No.: 13/406,431

(22) Filed: Feb. 27, 2012

(51) Int. Cl. H03H 7/38; H03F 1/00

(52) U.S. Cl. 330/185; 333/32; 330/192

(57) ABSTRACT

An impedance matching circuit is disclosed. The impedance matching circuit includes two or more mutually coupled inductors. A total self inductance of the impedance matching circuit is less than a corresponding impedance matching circuit that includes inductors that are not mutually coupled. The two or more mutually coupled inductors may have known current ratios that match current ratios in the corresponding impedance matching circuit.

### TECHNICAL FIELD

The present disclosure relates generally to electronic communications. More specifically, the present disclosure relates to systems and methods for a mutually coupled matching network.

### BACKGROUND

Wireless communication systems are widely deployed to provide various types of communication content such as voice, video, data, and so on. These systems may be multiple-access systems capable of supporting simultaneous communication of multiple terminals with one or more base stations.

A terminal or a base station may include one or more integrated circuits. These integrated circuits may include analog and digital circuitry necessary for wireless communication. Such circuitry may include inductors. As the technology used to build integrated circuits progresses, active elements on the integrated circuit such as transistors continue to decrease in size. Passive elements on the integrated circuit may not decrease in size relative to the active elements. Therefore, integrated circuits built with progressive technology may require increasing percentages of area on the integrated circuit for passive elements. Benefits may be realized by reducing the die area consumed by passive elements on an integrated circuit.

### SUMMARY

An impedance matching circuit is described. The impedance matching circuit includes two or more mutually coupled inductors. A total self inductance of the impedance matching circuit is less than a corresponding impedance matching circuit comprising inductors that are not mutually coupled.

The two or more mutually coupled inductors may use less area than the inductors that are not mutually coupled would use. The two or more mutually coupled inductors may have a higher inductor quality factor (Q) than the inductors that are not mutually coupled would have. The two or more mutually coupled inductors may form a transformer. The impedance matching circuit may be coupled between a source and a load. The two or more mutually coupled inductors may include a first inductor and a second inductor that are mutually coupled to each other. The first inductor may be coupled between the source and the load. The second inductor may be coupled between the load and ground. Alternatively, the first inductor may be coupled between the source and ground and the second inductor may be coupled between the source and the load.

The impedance matching circuit may be a differential mutually coupled matching circuit. The differential mutually coupled matching circuit may include a first input, a second input, a first output, a second output, a first inductor coupled between the first input and the first output, a second inductor coupled between the first output and the second output and a third inductor coupled between the second input and the second output. The first inductor, the second inductor and the third inductor may be mutually coupled to each other.

A first coupling having a first coupling coefficient may be between the first inductor and the third inductor. A second coupling having a second coupling coefficient may be between the first inductor and the second inductor. A third coupling having a third coupling coefficient may be between the second inductor and the third inductor. The impedance matching circuit may be in a wireless device. The impedance matching circuit may be coupled between a duplexer and a low noise amplifier in a receive chain. Alternatively, the impedance matching circuit may be coupled between duplexer and a power amplifier in a transmit chain.

A method for impedance matching is also described. A signal requiring impedance matching is received from a source. The signal is provided to an impedance matching circuit that includes two or more mutually coupled inductors. A total self inductance of the impedance matching circuit is less than a corresponding impedance matching circuit comprising inductors that are not mutually coupled. An output of the impedance matching circuit is provided to a load.

An apparatus is described. The apparatus includes means for receiving a signal requiring impedance matching from a source. The apparatus also includes means for providing the signal to an impedance matching circuit that includes two or more mutually coupled inductors. A total self inductance of the impedance matching circuit is less than a corresponding impedance matching circuit comprising inductors that are not mutually coupled. The apparatus further includes means for providing an output of the impedance matching circuit to a load.

### BRIEF DESCRIPTION OF THE DRAWINGS

FIG. 1 is a block diagram of an electronic device for use in the present systems and methods;

FIG. 2 is an example block diagram of a wireless device for use in the present systems and methods;

FIG. 3 is a circuit diagram illustrating the differences between a single-ended matching network and a single-ended mutually coupled matching network;

FIG. 4 is a layout diagram illustrating the differences between a single-ended matching network and a single-ended mutually coupled matching network;

FIG. 5 is a flow diagram of a method for using a mutually coupled matching network;

FIG. 6 is another circuit diagram illustrating the differences between a single-ended matching network and a single-ended mutually coupled matching network;

FIG. 7 is a circuit diagram illustrating the differences between a differential matching network and a differential mutually coupled matching network;

FIG. 8 is a layout diagram illustrating the differences between a differential matching network and a differential mutually coupled matching network;

FIG. 9 is a flow diagram of a method for designing a mutually coupled matching network;

FIG. 10 illustrates certain components that may be included within a base station; and

FIG. 11 illustrates certain components that may be included within a wireless communication device.

### DETAILED DESCRIPTION

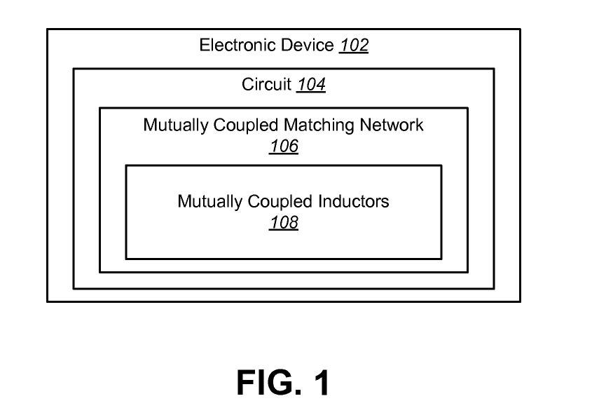

FIG. 1 is a block diagram of an electronic device 102 for use in the present systems and methods. The electronic device 102 may be a base station, a wireless communication device, or other device that uses electricity. The electronic device 102 may include a circuit 104 with a mutually coupled matching network 106. The mutually coupled matching network 106 may also be referred to as an impedance matching circuit with mutually coupled inductors.

Many electronic devices 102 may include matching networks. A matching network may use impedance matching to match the output impedance of a signal source to the input impedance of an electrical load. Impedance matching may maximize the power transfer and/or minimize reflections from the source and load. A matching network may often be used as part of a circuit 104 in the electronic device 102.

Matching circuit design often involves multiple inductor components. Inductors are passive devices; as active circuit process sizes decrease due to the advancement of the process technology, the sizes of passive devices remain the same. Thus, in smaller integrated circuit process sizes, inductors may dominate the die area used. The large form factor of inductors makes integration onto planar technology infeasible. One solution for matching networks is to use surface mount technology (SMT) components for the matching networks. Surface mount technology (SMT) components are components that are mounted to a circuit board (or integrated circuit). However, the use of surface mount technology (SMT) components may have many drawbacks in terms of board area and increases in the Bill of Material (BOM) (i.e., the total number of discrete surface mount technology (SMT) circuit components of the electronic device 102). The drawbacks of surface mount technology (SMT) components are increased when differential topologies are used and/or the number of RF bands increases.

Instead of using surface mount technology (SMT) components, a matching network on planar technology may be designed. Examples of planar technology include standard silicon technology, Silicon-on-Insulator (SOI), Passive-on-Glass (POG), Integrated Passive Devices (IPD), low temperature co-fired ceramic (LTCC) and Printed-Circuit Board (PCB). A matching network may include two or more mutually coupled inductors 108. A matching network using mutually coupled inductors 108 may be referred to as a mutually coupled matching network 106. The mutually coupled inductors 108 may also be referred to as integrated inductors. In a mutually coupled matching network 106, inductor-inductor impedance matching is performed using the mutually coupled inductors 108 in place of discrete inductors such as surface mount technology (SMT) inductors, on-chip inductors, hand-wound inductors, etc. The mutually coupled inductors 108 may be a transformer, and may thus be referred to as a single transformer.

By replacing the discrete inductors in a matching network with mutually coupled inductors 108, the layout area used by the mutually coupled inductors 108 on the circuit 104 may be reduced significantly (when compared to the layout area used by the discrete inductors). Furthermore, replacing the discrete inductors in a matching network with mutually coupled inductors 108 may result in a better matching performance (e.g., a better inductor quality factor (Q) and lower insertion loss). Replacing discrete inductors (with a known and constant current ratio) with mutually coupled inductors 108 may also be used for other configurations such as filters, oscillators, etc.

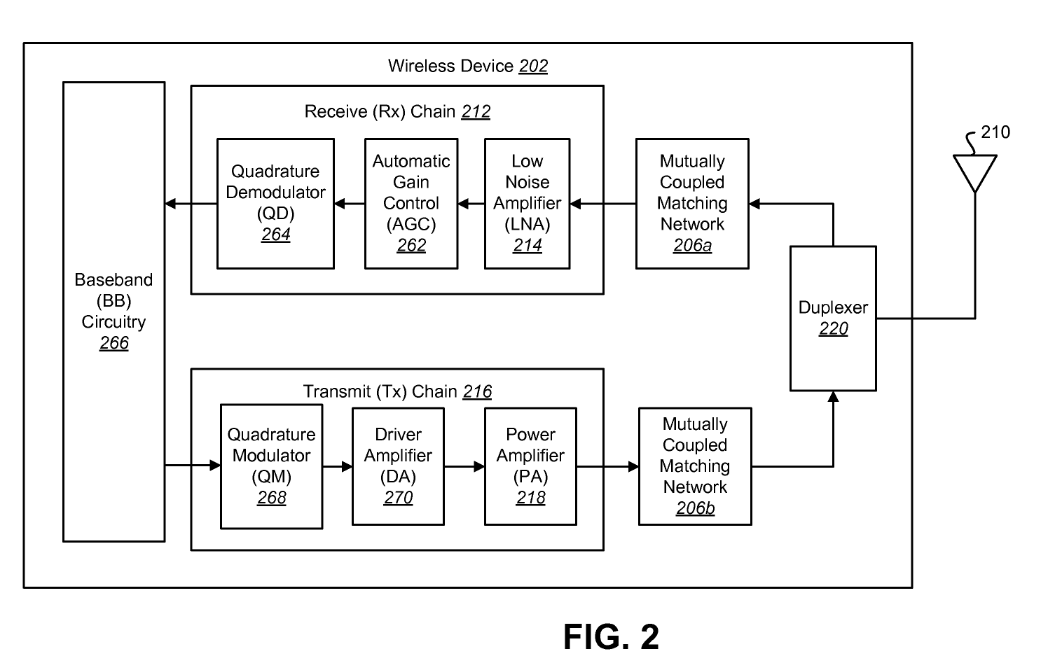

FIG. 2 is an example block diagram of a wireless device 202 for use in the present systems and methods. The wireless device 202 may be a base station or a wireless communication device. A base station is a station that communicates with one or more wireless communication devices. A base station may also be referred to as, and may include some or all of the functionality of, an access point, a broadcast transmitter, a NodeB, an evolved NodeB, etc. Each base station provides communication coverage for a particular geographic area. A base station may provide communication coverage for one or more wireless communication devices. The term “cell” can refer to a base station and/or its coverage area depending on the context in which the term is used.

A wireless communication device may also be referred to as, and may include some or all of the functionality of, a terminal, an access terminal, a user equipment (UE), a subscriber unit, a station, etc. A wireless communication device may be a cellular phone, a personal digital assistant (PDA), a wireless device, a wireless modem, a handheld device, a laptop computer, etc.

Communications in a wireless system (e.g., a multiple-access system) may be achieved through transmissions over a wireless link. Such a communication link may be established via a single-input and single-output (SISO), multiple-input and single-output (MISO) or a multiple-input and multiple-output (MIMO) system. A multiple-input and multiple-output (MIMO) system includes transmitter(s) and receiver(s) equipped, respectively, with multiple (NT) transmit antennas and multiple (NR) receive antennas for data transmission. SISO and MISO systems are particular instances of a multiple-input and multiple-output (MIMO) system. The multiple-input and multiple-output (MIMO) system can provide improved performance (e.g., higher throughput, greater capacity or improved reliability) if the additional dimensionalities created by the multiple transmit and receive antennas are utilized.

A wireless communication system may utilize both single-input and multiple-output (SIMO) and multiple-input and multiple-output (MIMO). A wireless communication system may be a multiple-access system capable of supporting communication with multiple wireless communication devices by sharing the available system resources (e.g., bandwidth and transmit power). Examples of such multiple-access systems include code division multiple access (CDMA) systems, wideband code division multiple access (W-CDMA) systems, time division multiple access (TDMA) systems, frequency division multiple access (FDMA) systems, orthogonal frequency division multiple access (OFDMA) systems, single-carrier frequency division multiple access (SC-FDMA) systems, 3^{rd} Generation Partnership Project (3GPP) Long Term Evolution (LTE) systems and spatial division multiple access (SDMA) systems.

The terms “networks” and “systems” are often used interchangeably. A CDMA network may implement a radio technology such as Universal Terrestrial Radio Access (UTRA), cdma2000, etc. UTRA includes W-CDMA and Low Chip Rate (LCR) while cdma2000 covers IS-2000, IS-95 and IS-856 standards. A TDMA network may implement a radio technology such as Global System for Mobile Communications (GSM). An OFDMA network may implement a radio technology such as Evolved UTRA (E-UTRA), IEEE 802.11, IEEE 802.16, IEEE 802.20, Flash-OFDMA, etc. UTRA, E-UTRA, and GSM are part of Universal Mobile Telecommunication System (UMTS). Long Term Evolution (LTE) is a release of UMTS that uses E-UTRA. UTRA, E-UTRA, GSM, UMTS and LTE are described in documents from an organization named “3rd Generation Partnership Project” (3GPP). cdma2000 is described in documents from an organization named “3rd Generation Partnership Project 2” (3GPP2). For clarity, certain aspects of the techniques are described below for LTE, and LTE terminology is used in much of the description below.

A wireless device 202 may include a receive (Rx) chain 212. Signals received by an antenna 210 on the wireless device 202 may be provided to a low noise amplifier (LNA) 214 in the receive (Rx) chain 212. An impedance matching network may be needed between a duplexer 220 and the low noise amplifier (LNA) 214. The duplexer 220 may be coupled to the antenna 210. In one configuration, the impedance matching network may be a mutually coupled matching network 206a. The receive (Rx) chain 212 may also include an automatic gain control (AGC) 262 coupled to an output of the low noise amplifier (LNA) 214. The output of the automatic gain control (AGC) 262 may be passed through a quadrature demodulator (QD) 264 as part of the receive (Rx) chain 212 before being passed to baseband (BB) circuitry 266.

A wireless device 202 may also include a transmit (Tx) chain 216. The transmit (Tx) chain 216 may prepare transmit signals to be transmitted by the antenna 210 on the wireless device 202. The transmit (Tx) chain 216 may include a quadrature modulator (QM) 268 coupled to the baseband (BB) circuitry 266. The output of the quadrature modulator (QM) 268 may be passed through a driver amplifier (DA) 270 in the transmit (Tx) chain 216. The output of the driver amplifier (DA) 270 may then be amplified using a power amplifier (PA) 218 in the transmit (Tx) chain 216. An impedance matching network may be needed between the power amplifier (PA) 218 and the duplexer 220. In one configuration, the impedance matching network may be a mutually coupled matching network 206b.

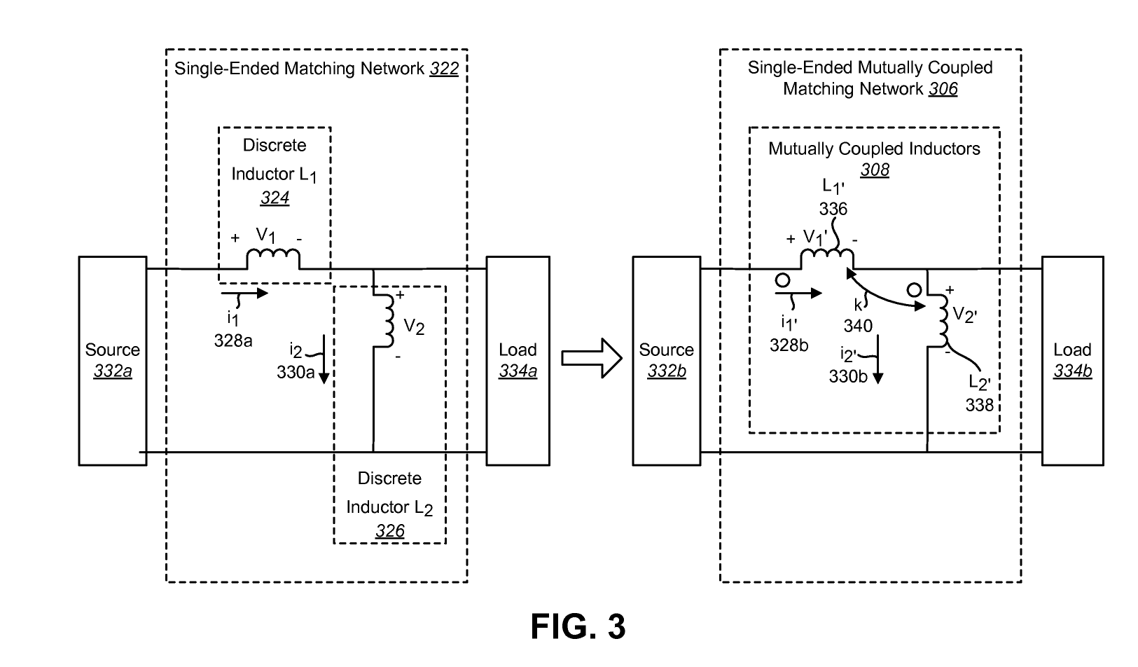

FIG. 3 is a circuit diagram illustrating the differences between a single-ended matching network 322 and a single-ended mutually coupled matching network 306. The single-ended mutually coupled matching network 306 of FIG. 3 may be one configuration of the mutually coupled matching network 106 of FIG. 1. A single-ended matching network 322 may provide impedance matching between a source 332a and a load 334a. For example, the source 332a may be a receiving antenna 210 and the load 334a may be a low noise amplifier (LNA) 214. As another example, the source 332a may be a power amplifier (PA) 218 and the load 334a may be a duplexer 220.

The single-ended matching network 322 may include a first discrete inductor L1 324 and a second discrete inductor L2 326. The first discrete inductor L1 324 may be coupled between the source 332a and the load 334a. The second discrete inductor L2 326 may be coupled between the load 334a and a ground line. A voltage v1 may be across the first discrete inductor L1 324 and a current i1 328a may flow through the first discrete inductor L1 324. The voltage v1 may be expressed using Equation (1):

$${v}_{1} = - {L}_{1} \frac{d {i}_{1}}{d t} . \qquad ( 1 )$$

A voltage v2 may be across the second discrete inductor L2 and a current i2 330a may flow through the second discrete inductor L2 326. The voltage v2 may be expressed using Equation (2):

$${v}_{2} = - {L}_{2} \frac{d {i}_{2}}{d t} . \qquad ( 2 )$$

The first discrete inductor L1 324 and the second discrete inductor L2 326 may thus have a known current ratio i1/i2. To obtain a single-ended mutually coupled matching network 306, the first discrete inductor L1 324 and the second discrete inductor L2 326 may be replaced with mutually coupled inductors 308 L1′ 336 and L2′ 338.

The single-ended mutually coupled matching network 306 may provide impedance matching between a source 332b and a load 334b. The single-ended mutually coupled matching network 306 may include mutually coupled inductors 308 L1′ 336 and L2′ 338. The mutually coupled inductors 308 L1′ 336 and L2′ 338 may replace the first discrete inductor L1 324 and the second discrete inductor L2 326. A voltage of v1′ may be across L1′ 336 and a voltage of v2′ may be across L2′ 338. A current i1 328b may flow through L1′ 336 and a current i2 330b may flow through L2′ 338. Thus, the currents of the single-ended matching network 322 and the single-ended mutually coupled matching network 306 may be the same. The voltage v1′ across the inductor L1′ 336 may be expressed using Equation (3):

$${v}_{1} = - ( {L}_{1}^{′} \frac{d {i}_{1}^{′}}{d t} + k \sqrt{{L}_{1}^{′} {L}_{2}^{′}} \frac{d {i}_{2}^{′}}{d t} ) . \qquad ( 3 )$$

In Equation (3), k 340 is the coupling coefficient between the mutually coupled inductors 308 L1′ 336 and L2′ 328. The voltage v2′ across the inductor L2′ 328 may be expressed using Equation (4):

$${v}_{2} = - ( {L}_{2}^{′} \frac{d {i}_{2}^{′}}{d t} + k \sqrt{{L}_{1}^{′} {L}_{2}^{′}} \frac{d {i}_{1}^{′}}{d t} ) . \qquad ( 4 )$$

The voltage v1′ may then be set equal to the voltage v1, resulting in Equation (5):

$${L}_{1} \frac{d {i}_{1}}{d t} = {L}_{1}^{′} \frac{d {i}_{1}^{′}}{d t} + k \sqrt{{L}_{1}^{′} {L}_{2}^{′}} \frac{d {i}_{2}^{′}}{d t} . \qquad ( 5 )$$

Likewise, the voltage v2′ may be set equal to the voltage v2, resulting in Equation (6):

$${L}_{2} \frac{d {i}_{2}}{d t} = {L}_{2}^{′} \frac{d {i}_{2}^{′}}{d t} + k \sqrt{{L}_{1}^{′} {L}_{2}^{′}} \frac{d {i}_{1}^{′}}{d t} . \qquad ( 6 )$$

Solving Equation (5) and Equation (6) for L1 324 results in Equation (7):

$${L}_{1} = {L}_{1}^{′} - \frac{1}{2} {k}^{2} {L}_{1}^{′} ( 1 - \sqrt{1 + \frac{4}{{k}^{2}} \frac{{L}_{2} {i}_{2}^{2}}{{L}_{1} {i}_{1}^{2}}} ) . \qquad ( 7 )$$

Likewise, solving Equation (5) and Equation (6) for L2 326 results in Equation ((8):

$${L}_{2} = {L}_{2}^{′} - \frac{1}{2} {k}^{2} {L}_{2}^{′} ( 1 - \sqrt{1 + \frac{4}{{k}^{2}} \frac{{L}_{1} {i}_{1}^{2}}{{L}_{21} {i}_{2}^{2}}} ) . \qquad ( 8 )$$

Because L1 324 and L2 326 are given, Equation (7) and Equation (8) may be used to determine the values for L1′ 336 and L2′ 338. The total self inductance for the single-ended mutually coupled matching network 306 may be less than the total self inductance of the single-ended matching network 322. In other words, L1′+L2′<L1+L2. Furthermore, the area consumption of the mutually coupled inductors 308 L1′ 336 and L2′ 338 may be significantly less than the area consumption of the first discrete inductor L1 324 and the second discrete inductor L2 326. Equation (5) through Equation (8) may be used for calculating the values for L1′ 336 and L2′ 338. However, this is just one of the many ways that can be used for the design of the mutually coupled matching network 306. To derive Equation (5) through Equation (8), it may be assumed that i₁=i₁′, i₂=i₂′, v₁=v₁′ and v₂=v₂′. These assumptions may not yield the best optimized design.

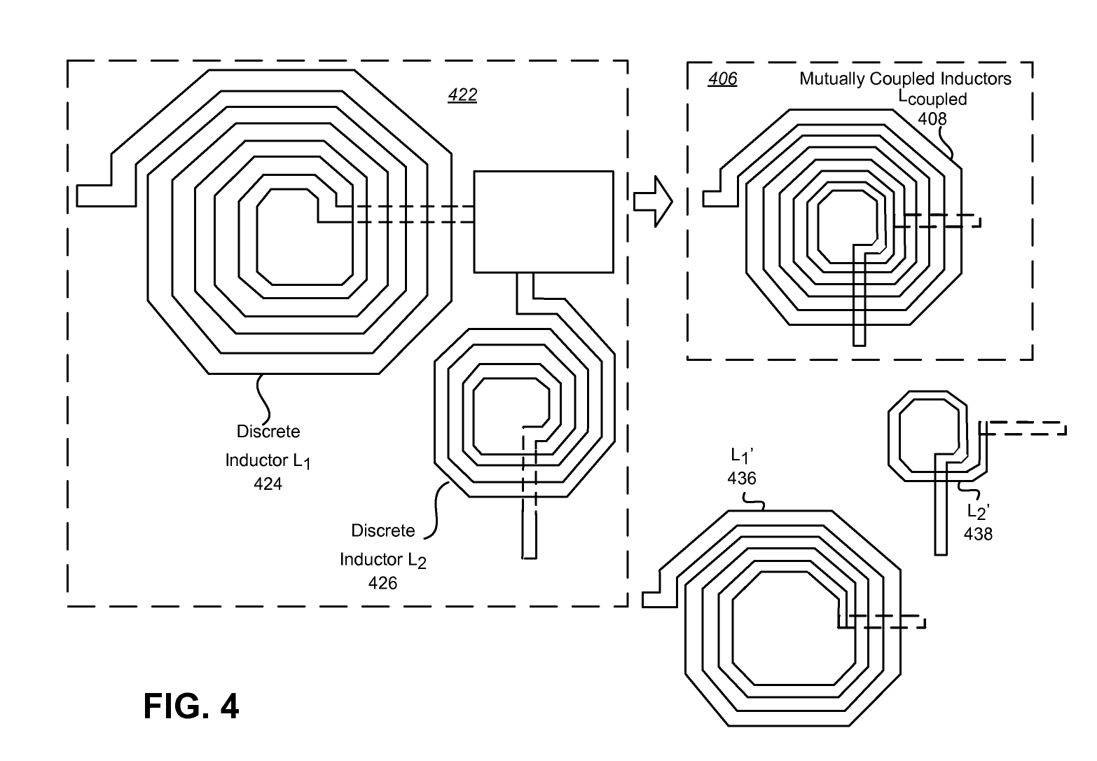

FIG. 4 is a layout diagram illustrating the differences between a single-ended matching network 422 and a single-ended mutually coupled matching network 406. The layout illustrated represents only one implementation of the single-ended matching network 422 and the corresponding single-ended mutually coupled matching network 406. Many other implementations may also be used.

The single-ended matching network 422 may include a first discrete inductor L1 424 and a second discrete inductor L2 426. The first discrete inductor L1 424 may be physically separated from the second discrete inductor L2 426 to prevent coupling. The single-ended mutually coupled matching network 406 may include mutually coupled inductors L_{coupled} 408 L1′ 436 and L2′ 438 (shown separately for illustration purposes). The inductor L1′ 436 has a self inductance of L1′. The value of L1′ is less than the value of L1. The inductor L2′ 438 has a self inductance of L2′. The value of L2′ is less than the value of L2. Furthermore, the value of L1′+L2′ is less than the value of L1+L2. Thus, the total self inductance of the mutually coupled inductors L_{coupled} 408 is less than the total self inductance of the single-ended matching network 422. The mutually coupled inductors L_{coupled} 408 L1′ 436 and L2′ 438 may couple each other (with a coupling coefficient k 340). The inductance of the mutually coupled inductors L_{coupled} 408 may be found using Equation (9):

L_{coupled}=L₁′+L₂′+2M. (9)

In Equation (9), M=k\sqrt{L₁′*L₂′}. The single-ended mutually coupled matching network 406 may use less die area on an circuit 104 than the single-ended matching network 422. Furthermore, the single-ended mutually coupled matching network 406 may have a higher inductor quality factor (Q) than the single-ended matching network 422.

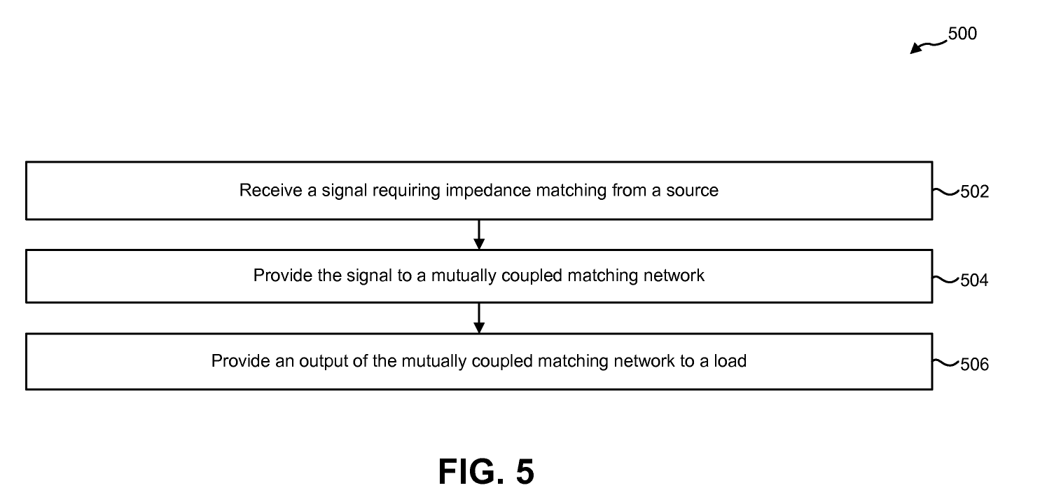

FIG. 5 is a flow diagram of a method 500 for using a mutually coupled matching network 106. The method 500 may be performed on an electronic device 102 in either the receiver side or the transmitter side. On the receiver side, the electronic device 102 may receive 502 a signal requiring impedance matching from a source 332b. For example, the source 332b may be a duplexer 220. The electronic device 102 may provide 504 the signal to a mutually coupled matching network 106. The mutually coupled matching network 106 may have two or more mutually coupled inductors 108, where the total self inductance of the mutually coupled matching network 106 is less than the inductance of a matching network. The electronic device 102 may also provide 506 an output of the mutually coupled matching network 106 to a load 334b. For example, the load 334b may be a low noise amplifier (LNA) 214 or a duplexer 220.

On the transmitter side, the electronic device 102 may receive 502 a signal requiring impedance matching from a source 332b. For example, the source 332b may be a power amplifier (PA) 218. The electronic device 102 may provide 504 the signal to a mutually coupled matching network 106. The electronic device 102 may also provide 506 an output of the mutually coupled matching network 106 to a load 334b. For example, the load 334b may be a duplexer 220.

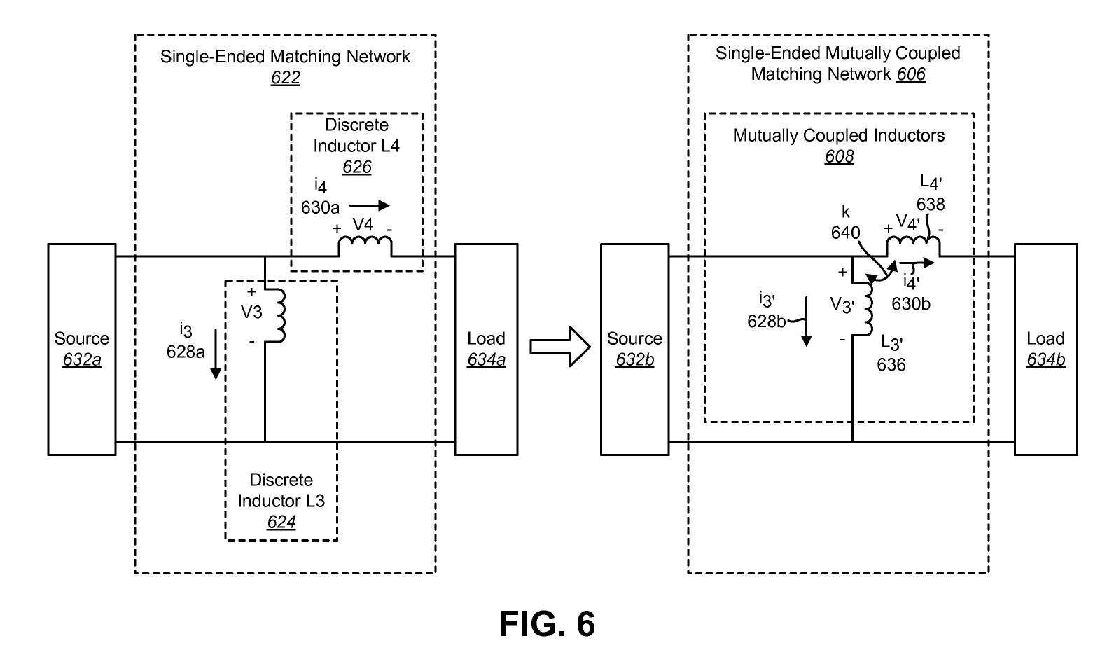

FIG. 6 is another circuit diagram illustrating the differences between a single-ended matching network 622 and a single-ended mutually coupled matching network 606. The single-ended matching network 622 may provide impedance matching between a source 632a and a load 634a. The single-ended matching network 622 may include a first discrete inductor L3 624 and a second discrete inductor L4 626. The first discrete inductor L3 624 may be coupled between the source 632a and ground. The second discrete inductor L4 626 may be coupled between the source 632a and the load 634a.

A voltage v3 may be across the first discrete inductor L3 624 and a current i3 628a may flow through the first discrete inductor L3 624. A voltage v4 may be across the second discrete inductor L4 626 and a current i4 630a may flow through the second discrete inductor L4 626. The first discrete inductor L3 624 and the second discrete inductor L4 626 may have a known current ratio of i3/i4. To obtain a single-ended mutually coupled matching network 606, the first discrete inductor L3 624 and the second discrete inductor L4 626 may be replaced with mutually coupled inductors 608 L3′ 636 and L4′ 638 with a coupling coefficient of k 640.

The single-ended mutually coupled matching network 606 may provide impedance matching between a source 632b and a load 634b. The single-ended mutually coupled matching network 606 may include mutually coupled inductors 608 L3′ 636 and L4′ 638. The mutually coupled inductors 608 L3′ 636 and L4′ 638 may replace the first discrete inductor L3 624 and the second discrete inductor L4 626 of the single-ended matching network 622. A voltage of v3′ may be across L3′ 636 and a voltage of v4′ may be across L4′ 638. A current i3′ 628b may flow through L3′ 636 and a current i4′ 630b may flow through L4′ 638.

The values for L3′ 636 and L4′ 638 may be found from the values of L3 624 and L4 626 using a similar analysis as that discussed above in relation to FIG. 3. The total self inductance for the single-ended mutually coupled matching network 606 may be less than the total self inductance of the single-ended matching network 622. In other words, L3′+L4′<L3 +L4. Furthermore, the area consumption of the mutually coupled inductors L3′ 636 and L4′ 638 on a circuit 104 may be significantly less than the area consumption of the first discrete inductor L3 624 and the second discrete inductor L4 626 on a circuit 104.

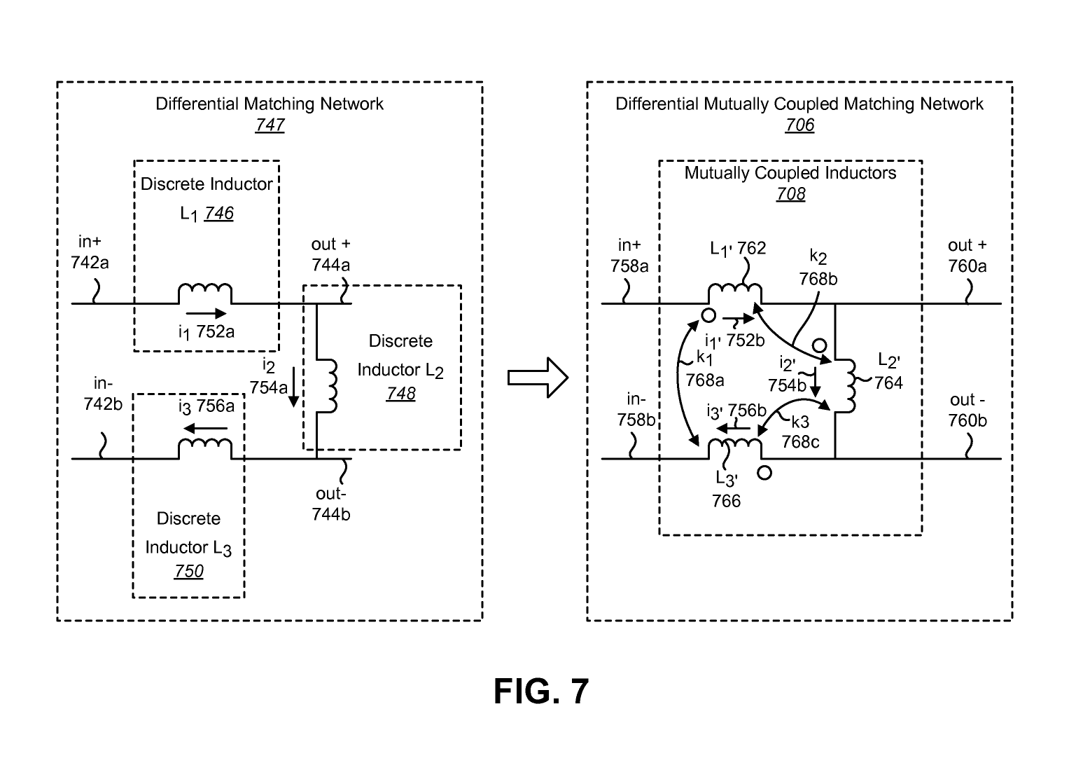

FIG. 7 is a circuit diagram illustrating the differences between a differential matching network 747 and a differential mutually coupled matching network 706. The differential mutually coupled matching network 706 of FIG. 7 may be one configuration of the mutually coupled matching network 106 of FIG. 1. The differential matching network 747 may provide impedance matching between a source (via an in+ input 742a and an in− input 742b) and a load (via an out+ output 744a and an out− output 744b). The differential matching network 747 may include a first discrete inductor L1 746, a second discrete inductor L2 748 and a third discrete inductor L3 750. The differential matching network 747 may include more than the three inductors shown. The first discrete inductor L1 746 may be coupled between the in+ input 742a and the out+ output 744a. The second discrete inductor L2 748 may be coupled between the out+ output 744a and the out− output 744b. The third discrete inductor L3 750 may be coupled between the in− input 742b and the out− output 744b.

A current i1 752a may flow through the first discrete inductor L1 746. A current i2 754a may flow through the second discrete inductor L2 748. A current i3 756a may flow through the third discrete inductor L3 750. The ratio between the currents i1 752a, i2 754a and i3 756a may be known. To obtain a differential mutually coupled matching network 706, the first discrete inductor L1 746, the second discrete inductor L2 748 and the third discrete inductor L3 750 of the differential matching network 747 may be replaced with mutually coupled inductors 708 L1′ 762, L2′ 764 and L3′ 766.

The differential mutually coupled matching network 706 may provide impedance matching between a source (via an in+ input 758a and an in− input 758b) and a load (via an out+ output 760a and an out− output 760b). The differential mutually coupled matching network 706 may include mutually coupled inductors 708 L1′ 762, L2′ 764 and L3′ 766. The differential mutually coupled matching network 706 may include more than three mutually coupled inductors 708, depending on the number of discrete inductors in the differential matching network 747. Thus, the concept of differential mutually coupled inductors 708 may be applied to any number of coupled inductors more than two (i.e., there are cases where a two coupled inductors may be utilized for differential mutually coupled inductors 708). The mutually coupled inductors 708 L1′ 762, L2′ 764 and L3′ 766 may replace the first discrete inductor L1 746, the second discrete inductor L2 748 and the third discrete inductor L3 750. A current i1′ 752b may flow through L1′ 762, a current i2′ 754b may flow through L2′ 764 and a current i3′ 756b may flow through L3′ 766.

A first coupling may occur between the inductor L1′ 762 and the inductor L3′ 766. The first coupling may have a coupling coefficient of k1 768a. A second coupling may occur between the inductor L1′ 762 and the inductor L2′ 764. The second coupling may have a coupling coefficient of k2 768b. A third coupling may occur between the inductor L2′ 764 and the inductor L3′ 766. The third coupling may have a coupling coefficient of k3 768c.

The values for L1′ 762, L2′ 764 and L3′ 766 may be found from the values of L1 746, L2 748 and L3 750 using a similar analysis as that discussed above in relation to FIG. 3. The total self inductance for the differential mutually coupled matching network 706 may be less than the total self inductance of the differential matching network 747. In other words, L1′+L2′+L3′<L1+L2+L3. Furthermore, the area consumption of the mutually coupled inductors 708 L1′ 762, L2′ 764 and L3′ 766 on a circuit 104 may be significantly less than the area consumption of the first discrete inductor L1 746, the second discrete inductor L2 748 and the third discrete inductor L3 750 on a circuit 104.

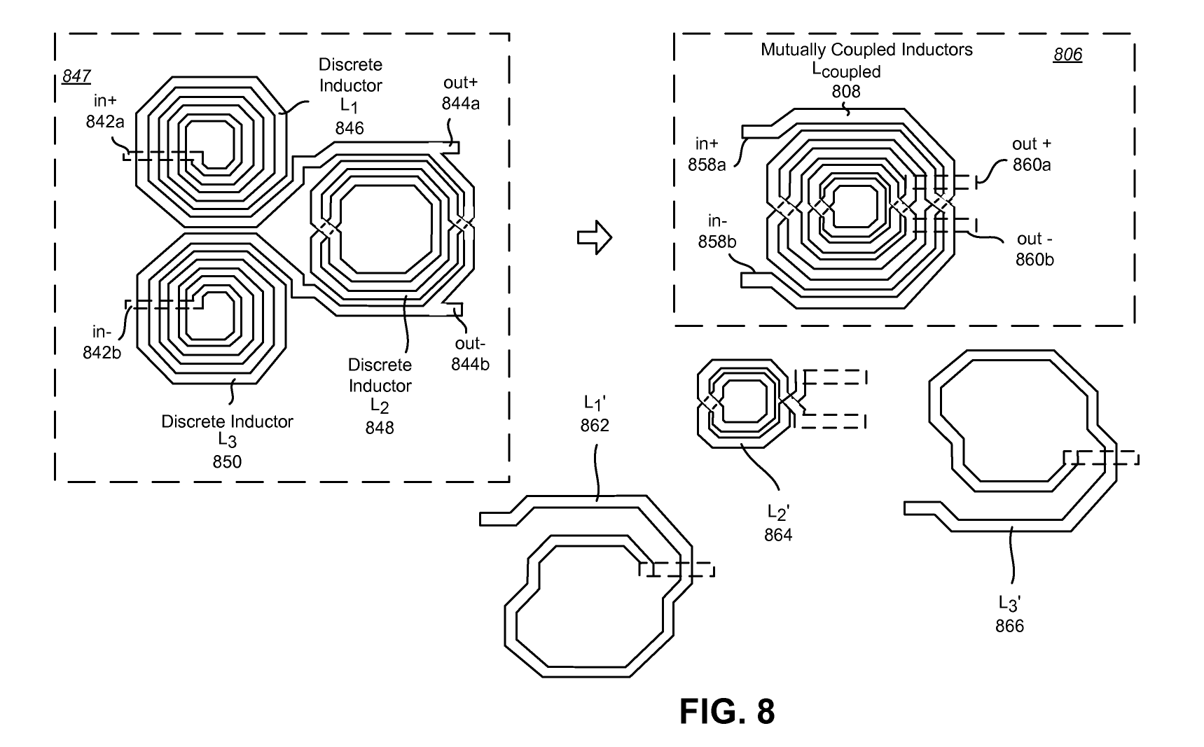

FIG. 8 is a layout diagram illustrating the differences between a differential matching network 847 and a differential mutually coupled matching network 806. The layouts illustrated represent only one implementation of the differential matching network 847 and the differential mutually coupled matching network 806. Many other implementations may also be used.

The differential matching network 847 may provide impedance matching between a source (via an in+ input 842a and an in− input 842b) and a load (via an out+ output 844a and an out− output 844b). The differential matching network 847 may include a first discrete inductor L1 846, a second discrete inductor L2 848 and a third discrete inductor L3 850. The first discrete inductor L1 846 may be coupled between the in+ input 842a and the out+ output 844a. The second discrete inductor L2 848 may be coupled between the out+ output 844a and the out− output 844b. The third discrete inductor L3 850 may be coupled between the in− input 842b and the out− output 844b. The first discrete inductor L1 846, the second discrete inductor L2 848 and the third discrete inductor L3 850 may be physically separated from each other to prevent coupling.

The differential mutually coupled matching network 806 may provide impedance matching between a source (via an in+ input 858a and an in− input 858b) and a load (via an out+ output 860a and an out− output 860b). The differential mutually coupled matching network 806 may include mutually coupled inductors 808 L1′ 862, L2′ 864 and L3′ 866 (the mutually coupled inductors 808 L1′ 862, L2′ 864 and L3′ 866 are shown separately for illustration purposes). The mutually coupled inductors 808 L1′ 862, L2′ 864 and L3′ 866 may couple each other (with coupling coefficients k1 768a, k2 768b and k3 768c).

The inductor L1′ 862 has a self inductance of L1′. The value of L1′ is less than the value of L1. The inductor L2′ 864 has a self inductance of L2′. The value of L2′ is less than the value of L2. The inductor L3′ 866 has a self inductance of L3′. The value of L3′ is less than the value of L3. Furthermore, the value of L1′+L2′+L3′ is less than the value of L1+L2+L3. Thus, the total self inductance of the mutually coupled inductors L_{coupled} 808 is less than the total self inductance of the differential matching network 847. The mutually coupled inductors L_{coupled} 808 L1′ 862 and L3′ 866 may couple each other (with a coupling coefficient k1 768a). The mutually coupled inductors L_{coupled} 808 L1′ 862 and L2′ 864 may couple each other (with a coupling coefficient k2 768b). The mutually coupled inductors L_{coupled} 808 L2′ 864 and L3′ 866 may couple each other (with a coupling coefficient k3 768c). The inductance of the mutually coupled inductors L_{coupled} 808 may be found using Equation (10):

L_{coupled}=L₁′+L₂′+L₃′+2M₁+2M₂+2M₃. (10)

In Equation (10), M₁=k₁\sqrt{L₁′*L₃′}, M₂=k₂\sqrt{L₁′*L₂′} and M₃=k₃\sqrt{L₂′*L₃′}. The differential mutually coupled matching network 806 may use less die area on a circuit 104 than the differential matching network 847. Furthermore, the differential mutually coupled matching network 806 may have a higher inductor quality factor (Q) than the differential matching network 847.

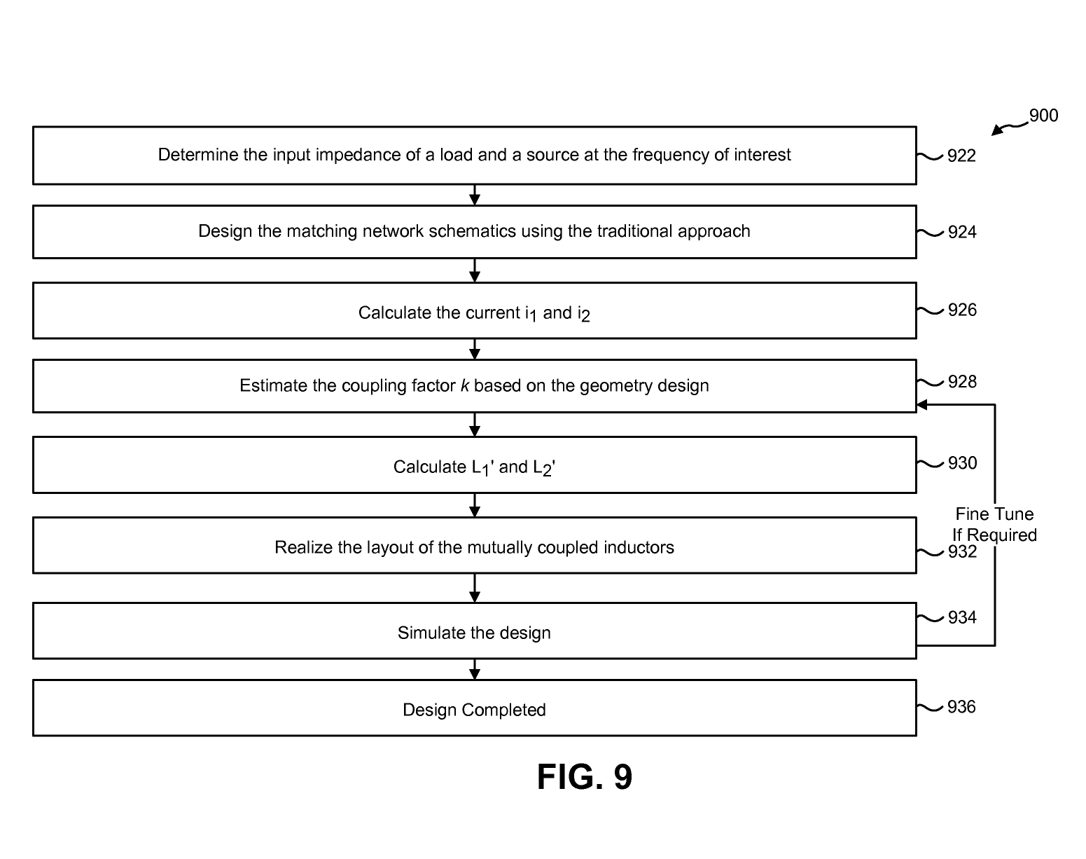

FIG. 9 is a flow diagram of a method 900 for designing a mutually coupled matching network. In one configuration, the method 900 may be performed using automated design tools. An input impedance of a source 332 and a load 334 at the frequency of interest may be determined 922. The matching network schematics may be designed 924 using the traditional approach. The current i1 328 and the current i2 330a may be calculated 926. The coupling factor k 340 may be estimated 928 based on the geometry design.

The new inductor values L1′ 336 and L2′ 338 may be calculated 930. The layout of the mutually coupled inductors 308 may then be realized 932. The design may then be simulated 934. If required, fine tuning may be performed and the coupling factor k 340 may again be estimated 928 based on the geometry design. The design may then be completed 936.

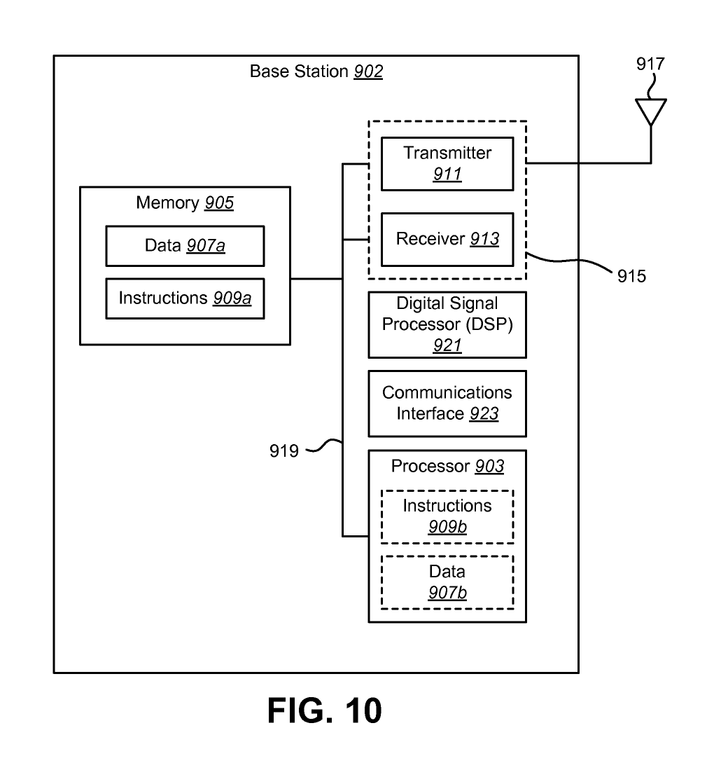

FIG. 10 illustrates certain components that may be included within a base station 902. A base station may also be referred to as, and may include some or all of the functionality of, an access point, a broadcast transmitter, a NodeB, an evolved NodeB, etc. The base station 902 includes a processor 903. The processor 903 may be a general purpose single- or multi-chip microprocessor (e.g., an ARM), a special purpose microprocessor (e.g., a digital signal processor (DSP)), a microcontroller, a programmable gate array, etc. The processor 903 may be referred to as a central processing unit (CPU). Although just a single processor 903 is shown in the base station 902 of FIG. 10, in an alternative configuration, a combination of processors (e.g., an ARM and DSP) could be used.

The base station 902 also includes memory 905. The memory 905 may be any electronic component capable of storing electronic information. The memory 905 may be embodied as random access memory (RAM), read only memory (ROM), magnetic disk storage media, optical storage media, flash memory devices in RAM, on-board memory included with the processor, EPROM memory, EEPROM memory, registers, and so forth, including combinations thereof.

Data 907a and instructions 909a may be stored in the memory 905. The instructions 909a may be executable by the processor 903 to implement the methods disclosed herein. Executing the instructions 909a may involve the use of the data 907a that is stored in the memory 905. When the processor 903 executes the instructions 909a, various portions of the instructions 909b may be loaded onto the processor 903, and various pieces of data 907b may be loaded onto the processor 903.

The base station 902 may also include a transmitter 911 and a receiver 913 to allow transmission and reception of signals to and from the base station 902. The transmitter 911 and receiver 913 may be collectively referred to as a transceiver 915. An antenna 917 may be electrically coupled to the transceiver 915. The base station 902 may also include (not shown) multiple transmitters, multiple receivers, multiple transceivers and/or multiple antennas.

The base station 902 may include a digital signal processor (DSP) 921. The base station 902 may also include a communications interface 923. The communications interface 923 may allow a user to interact with the base station 902.

The various components of the base station 902 may be coupled together by one or more buses, which may include a power bus, a control signal bus, a status signal bus, a data bus, etc. For the sake of clarity, the various buses are illustrated in FIG. 10 as a bus system 919.

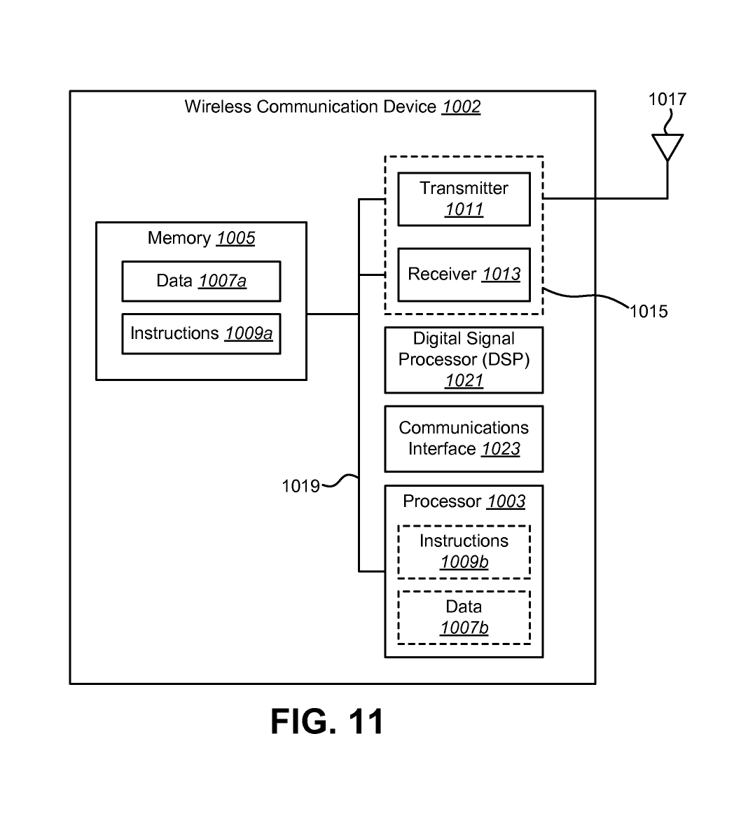

FIG. 11 illustrates certain components that may be included within a wireless communication device 1002. The wireless communication device 1002 may be an access terminal, a mobile station, a user equipment (UE), etc. The wireless communication device 1002 includes a processor 1003. The processor 1003 may be a general purpose single- or multi-chip microprocessor (e.g., an ARM), a special purpose microprocessor (e.g., a digital signal processor (DSP)), a microcontroller, a programmable gate array, etc. The processor 1003 may be referred to as a central processing unit (CPU). Although just a single processor 1003 is shown in the wireless communication device 1002 of FIG. 11, in an alternative configuration, a combination of processors (e.g., an ARM and DSP) could be used.

The wireless communication device 1002 also includes memory 1005. The memory 1005 may be any electronic component capable of storing electronic information. The memory 1005 may be embodied as random access memory (RAM), read-only memory (ROM), magnetic disk storage media, optical storage media, flash memory devices in RAM, on-board memory included with the processor, EPROM memory, EEPROM memory, registers, and so forth, including combinations thereof.

Data 1007a and instructions 1009a may be stored in the memory 1005. The instructions 1009a may be executable by the processor 1003 to implement the methods disclosed herein. Executing the instructions 1009a may involve the use of the data 1007a that is stored in the memory 1005. When the processor 1003 executes the instructions 1009a, various portions of the instructions 1009b may be loaded onto the processor 1003, and various pieces of data 1007b may be loaded onto the processor 1003.

The wireless communication device 1002 may also include a transmitter 1011 and a receiver 1013 to allow transmission and reception of signals to and from the wireless communication device 1002. The transmitter 1011 and receiver 1013 may be collectively referred to as a transceiver 1015. An antenna 1017 may be electrically coupled to the transceiver 1015. The wireless communication device 1002 may also include (not shown) multiple transmitters, multiple receivers, multiple transceivers and/or multiple antennas.

The wireless communication device 1002 may include a digital signal processor (DSP) 1021. The wireless communication device 1002 may also include a communications interface 1023. The communications interface 1023 may allow a user to interact with the wireless communication device 1002.

The various components of the wireless communication device 1002 may be coupled together by one or more buses, which may include a power bus, a control signal bus, a status signal bus, a data bus, etc. For the sake of clarity, the various buses are illustrated in FIG. 11 as a bus system 1019.

The techniques described herein may be used for various communication systems, including communication systems that are based on an orthogonal multiplexing scheme. Examples of such communication systems include Orthogonal Frequency Division Multiple Access (OFDMA) systems, Single-Carrier Frequency Division Multiple Access (SC-FDMA) systems, and so forth. An OFDMA system utilizes orthogonal frequency division multiplexing (OFDM), which is a modulation technique that partitions the overall system bandwidth into multiple orthogonal sub-carriers. These sub-carriers may also be called tones, bins, etc. With OFDM, each sub-carrier may be independently modulated with data. An SC-FDMA system may utilize interleaved FDMA (IFDMA) to transmit on sub-carriers that are distributed across the system bandwidth, localized FDMA (LFDMA) to transmit on a block of adjacent sub-carriers, or enhanced FDMA (EFDMA) to transmit on multiple blocks of adjacent sub-carriers. In general, modulation symbols are sent in the frequency domain with OFDM and in the time domain with SC-FDMA.

In the above description, reference numbers have sometimes been used in connection with various terms. Where a term is used in connection with a reference number, this may be meant to refer to a specific element that is shown in one or more of the Figures. Where a term is used without a reference number, this may be meant to refer generally to the term without limitation to any particular Figure.

The term “determining” encompasses a wide variety of actions and, therefore, “determining” can include calculating, computing, processing, deriving, investigating, looking up (e.g., looking up in a table, a database or another data structure), ascertaining and the like. Also, “determining” can include receiving (e.g., receiving information), accessing (e.g., accessing data in a memory) and the like. Also, “determining” can include resolving, selecting, choosing, establishing and the like.

The phrase “based on” does not mean “based only on,” unless expressly specified otherwise. In other words, the phrase “based on” describes both “based only on” and “based at least on.”

The functions described herein may be stored as one or more instructions on a processor-readable or computer-readable medium. The term “computer-readable medium” refers to any available medium that can be accessed by a computer or processor. By way of example, and not limitation, such a medium may comprise RAM, ROM, EEPROM, flash memory, CD-ROM or other optical disk storage, magnetic disk storage or other magnetic storage devices, or any other medium that can be used to store desired program code in the form of instructions or data structures and that can be accessed by a computer or processor. Disk and disc, as used herein, includes compact disc (CD), laser disc, optical disc, digital versatile disc (DVD), floppy disk and Blu-ray® disc where disks usually reproduce data magnetically, while discs reproduce data optically with lasers. It should be noted that a computer-readable medium may be tangible and non-transitory. The term “computer-program product” refers to a computing device or processor in combination with code or instructions (e.g., a “program”) that may be executed, processed or computed by the computing device or processor. As used herein, the term “code” may refer to software, instructions, code or data that is/are executable by a computing device or processor.

Software or instructions may also be transmitted over a transmission medium. For example, if the software is transmitted from a website, server, or other remote source using a coaxial cable, fiber optic cable, twisted pair, digital subscriber line (DSL) or wireless technologies such as infrared, radio and microwave, then the coaxial cable, fiber optic cable, twisted pair, DSL or wireless technologies such as infrared, radio and microwave are included in the definition of transmission medium.

Further, it should be appreciated that modules and/or other appropriate means for performing the methods and techniques described herein, such as those illustrated by FIG. 8, can be downloaded and/or otherwise obtained by a device. For example, a device may be coupled to a server to facilitate the transfer of means for performing the methods described herein. Alternatively, various methods described herein can be provided via a storage means (e.g., random access memory (RAM), read-only memory (ROM), a physical storage medium such as a compact disc (CD) or floppy disk, etc.), such that a device may obtain the various methods upon coupling or providing the storage means to the device. Moreover, any other suitable technique for providing the methods and techniques described herein to a device can be utilized.

The methods disclosed herein comprise one or more steps or actions for achieving the described method. The method steps and/or actions may be interchanged with one another without departing from the scope of the claims. In other words, unless a specific order of steps or actions is required for proper operation of the method that is being described, the order and/or use of specific steps and/or actions may be modified without departing from the scope of the claims.

Further, it should be appreciated that modules and/or other appropriate means for performing the methods and techniques described herein, such as those illustrated by FIG. 5, can be downloaded and/or otherwise obtained by a device. For example, a device may be coupled to a server to facilitate the transfer of means for performing the methods described herein. Alternatively, various methods described herein can be provided via a storage means (e.g., random access memory (RAM), read-only memory (ROM), a physical storage medium such as a compact disc (CD) or floppy disk, etc.), such that a device may obtain the various methods upon coupling or providing the storage means to the device. Moreover, any other suitable technique for providing the methods and techniques described herein to a device can be utilized.

It is to be understood that the claims are not limited to the precise configuration and components illustrated above. Various modifications, changes and variations may be made in the arrangement, operation and details of the systems, methods, and apparatus described herein without departing from the scope of the claims.

No claim element is to be construed under the provisions of 35 U.S.C. §112, sixth paragraph, unless the element is expressly recited using the phrase “means for” or, in the case of a method claim, the element is recited using the phrase “step for.”

What is claimed is:

1. An impedance matching circuit comprising two or more mutually coupled inductors, wherein a total self inductance of the impedance matching circuit is less than a corresponding impedance matching circuit comprising inductors that are not mutually coupled.

2. The impedance matching circuit of claim 1, wherein the two or more mutually coupled inductors use less area than the inductors that are not mutually coupled would use.

3. The impedance matching circuit of claim 1, wherein the two or more mutually coupled inductors have a higher inductor quality factor (Q) than the inductors that are not mutually coupled would have.

4. The impedance matching circuit of claim 1, wherein the two or more mutually coupled inductors form a transformer.

5. The impedance matching circuit of claim 1, wherein the impedance matching circuit is coupled between a source and a load.

6. The impedance matching circuit of claim 5, wherein the two or more mutually coupled inductors comprise a first inductor and a second inductor that are mutually coupled to each other, wherein the first inductor is coupled between the source and the load, and wherein the second inductor is coupled between the load and ground.

7. The impedance matching circuit of claim 5, wherein the two or more mutually coupled inductors comprise a first inductor and a second inductor that are mutually coupled to each other, wherein the first inductor is coupled between the source and ground, and wherein the second inductor is coupled between the source and the load.

8. The impedance matching circuit of claim 5, wherein the impedance matching circuit is a differential mutually coupled matching circuit comprising:
a first input;
a second input;
a first output;
a second output;
a first inductor coupled between the first input and the first output;
a second inductor coupled between the first output and the second output; and
a third inductor coupled between the second input and the second output,
wherein the first inductor, the second inductor and the third inductor are mutually coupled to each other.

9. The impedance matching circuit of claim 8, wherein a first coupling having a first coupling coefficient is between the first inductor and the third inductor, wherein a second coupling having a second coupling coefficient is between the first inductor and the second inductor, and wherein a third coupling having a third coupling coefficient is between the second inductor and the third inductor.

10. The impedance matching circuit of claim 5, wherein the impedance matching circuit is in a wireless device, and wherein the impedance matching circuit is coupled between a duplexer and a low noise amplifier in a receive chain.

11. The impedance matching circuit of claim 5, wherein the impedance matching circuit is in a wireless device, and wherein the impedance matching circuit is coupled between duplexer and a power amplifier in a transmit chain.

12. A method for impedance matching, the method comprising:
receiving a signal requiring impedance matching from a source;
providing the signal to an impedance matching circuit comprising two or more mutually coupled inductors, wherein a total self inductance of the impedance matching circuit is less than a corresponding impedance matching circuit comprising inductors that are not mutually coupled; and
providing an output of the impedance matching circuit to a load.

13. The method of claim 12, wherein the impedance matching circuit is part of an integrated circuit.

14. The method of claim 13, wherein the two or more mutually coupled inductors use less area on the integrated circuit than the inductors that are not mutually coupled would use.

15. The method of claim 12, wherein the two or more mutually coupled inductors have a higher inductor quality factor (Q) than the inductors that are not mutually coupled would have.

16. The method of claim 12, wherein the two or more mutually coupled inductors form a transformer.

17. The method of claim 12, wherein the impedance matching circuit comprises a first inductor and a second inductor that are mutually coupled to each other, wherein the first inductor is coupled between the source and the load, and wherein the second inductor is coupled between the load and ground.

18. The method of claim 12, wherein the impedance matching circuit comprises a first inductor and a second inductor that are mutually coupled to each other, wherein the first inductor is coupled between the source and ground, and wherein the second inductor is coupled between the source and the load.

19. The method of claim 12, wherein the impedance matching circuit is a differential mutually coupled matching circuit comprising:
a first input;
a second input;
a first output;
a second output;
a first inductor coupled between the first input and the first output;
a second inductor coupled between the first output and the second output; and
a third inductor coupled between the second input and the second output,
wherein the first inductor, the second inductor and the third inductor are mutually coupled to each other.

20. The method of claim 19, wherein a first coupling having a first coupling coefficient is between the first inductor and the third inductor, wherein a second coupling having a second coupling coefficient is between the first inductor and the second inductor, and wherein a third coupling having a third coupling coefficient is between the second inductor and the third inductor.

21. The method of claim 12, wherein the method is performed in a wireless device, wherein the source is an antenna, and wherein the load is a low noise amplifier in a receive chain.

22. The method of claim 12, wherein the method is performed in a wireless device, wherein the source is a power amplifier in a transmit chain, and wherein the load is a duplexer.

22. An apparatus, comprising:
means for receiving a signal requiring impedance matching from a source;
means for providing the signal to an impedance matching circuit comprising two or more mutually coupled inductors, wherein a total self inductance of the impedance matching circuit is less than a corresponding impedance matching circuit comprising inductors that are not mutually coupled; and
means for providing an output of the impedance matching circuit to a load.

23. The apparatus of claim 22, wherein the impedance matching circuit is part of an integrated circuit.

24. The apparatus of claim 23, wherein the two or more mutually coupled inductors use less area on the integrated circuit than the inductors that are not mutually coupled would use.

25. The apparatus of claim 22, wherein the two or more mutually coupled inductors have a higher inductor quality factor (Q) than the inductors that are not mutually coupled would have.

26. The apparatus of claim 22, wherein the two or more mutually coupled inductors form a transformer.
